(19) United States
(12) Patent Application Publication
(10) Pub. No.: US 2026/0163688 A1
(43) Pub. Date: Jun. 11, 2026

(54) SYSTEM INFORMATION VERSION INDICATION

(71) Applicant: QUALCOMM Incorporated, San Diego, CA (US)

(72) Inventors: Mostafa KHOSHNEVISAN, San Diego, CA (US); Yan ZHOU, San Diego, CA (US); Jing SUN, San Diego, CA (US); Tao LUO, San Diego, CA (US)

(21) Appl. No.: 18/974,453

(22) Filed: Dec. 9, 2024

(51) Int. Cl. H04L 5/00; H03M 13/45; H04W 72/1273

(52) U.S. Cl. CPC H04L 5/0044; H03M 13/45; H04W 72/1273

(57) ABSTRACT

Certain aspects of the present disclosure provide techniques for indicating a version of system information (SI). An example method, performed at a wireless node, generally includes obtaining at least one first physical downlink shared channel (PDSCH), storing information associated with at least one first version of system information (SI), the first version being conveyed in the at least one first PDSCH, obtaining, via a physical downlink channel, an indication of a second version of the SI, wherein the second version is to be obtained by the wireless node via a second PDSCH, wherein the physical downlink channel comprises a PDSCH or a physical downlink control channel (PDCCH), and performing one or more actions based on a comparison of the at least one first version and the second version.

### FIELD OF THE DISCLOSURE

Aspects of the present disclosure relate to wireless communications, and more particularly, to techniques for indicating a version of system information (SI).

### DESCRIPTION OF RELATED ART

Wireless communications systems are widely deployed to provide various telecommunication services such as telephony, video, data, messaging, broadcasts, or other similar types of services. These wireless communications systems may employ multiple-access technologies capable of supporting communications with multiple users by sharing available wireless communications system resources with those users.

Although wireless communications systems have made great technological advancements over many years, challenges still exist. For example, complex and dynamic environments can still attenuate or block signals between wireless transmitters and wireless receivers. Accordingly, there is a continuous desire to improve the technical performance of wireless communications systems, including, for example: improving speed and data carrying capacity of communications, improving efficiency of the use of shared communications mediums, reducing power used by transmitters and receivers while performing communications, improving reliability of wireless communications, avoiding redundant transmissions and/or receptions and related processing, improving the coverage area of wireless communications, increasing the number and types of devices that can access wireless communications systems, increasing the ability for different types of devices to intercommunicate, increasing the number and type of wireless communications mediums available for use, and the like. Consequently, there exists a need for further improvements in wireless communications systems to overcome the aforementioned technical challenges and others.

### SUMMARY

One aspect provides a method for wireless communication at a wireless node. The method includes obtaining at least one first physical downlink shared channel (PDSCH); storing information associated with at least one first version of system information (SI), the first version being conveyed in the at least one first PDSCH; obtaining, via a physical downlink channel, an indication of a second version of the SI, wherein the second version is to be obtained by the wireless node via a second PDSCH, wherein the physical downlink channel comprises a PDSCH or a physical downlink control channel (PDCCH); and performing one or more actions based on a comparison of the at least one first version and the second version.

Another aspect provides a method for wireless communication at a wireless node. The method includes outputting at least one first physical downlink shared channel (PDSCH) that conveys a first version of system information (SI); outputting, via a physical downlink channel, an indication of a second version of the SI, wherein the physical downlink channel comprises a PDSCH or a physical downlink control channel (PDCCH); and outputting a second PDSCH that conveys the second version of the SI.

Other aspects provide: an apparatus operable, configured, or otherwise adapted to perform any one or more of the aforementioned methods and/or those described elsewhere herein; a non-transitory, computer-readable media comprising instructions that, when executed (e.g., directly, indirectly, after pre-processing, without pre-processing) by one or more processors of an apparatus, cause the apparatus to perform the aforementioned methods as well as those described elsewhere herein; a computer program product embodied on a computer-readable storage medium comprising code for performing the aforementioned methods as well as those described elsewhere herein; and/or an apparatus comprising means for performing the aforementioned methods as well as those described elsewhere herein. By way of example, an apparatus may comprise a processing system, a device with a processing system, or processing systems cooperating over one or more networks.

The following description and the appended figures set forth certain features for purposes of illustration.

### BRIEF DESCRIPTION OF DRAWINGS

The appended figures depict certain features of the various aspects described herein and are not to be considered limiting of the scope of this disclosure.

FIG. 1 depicts an example wireless communications network.

FIG. 2 depicts an example disaggregated base station architecture.

FIG. 3 depicts aspects of an example base station and an example user equipment.

FIGS. 4A, 4B, 4C, and 4D depict various example aspects of data structures for a wireless communications network.

FIGS. 5A and 5B depict examples of remaining minimum system information (RMSI) multiplexing patterns.

FIG. 6 depicts an example of RMSI transmissions.

FIG. 7 depicts an example call flow diagram, in accordance with certain aspects of the present disclosure.

FIG. 8 depicts an example of RMSI processing, in accordance with certain aspects of the present disclosure.

FIG. 9 depicts an example of RMSI processing, in accordance with certain aspects of the present disclosure.

FIG. 10 depicts an example of RMSI processing, in accordance with certain aspects of the present disclosure.

FIG. 11 depicts an example of RMSI processing, in accordance with certain aspects of the present disclosure.

FIG. 12 depicts an example of RMSI processing, in accordance with certain aspects of the present disclosure.

FIG. 13 depicts a method for wireless communications.

FIG. 14 depicts a method for wireless communications.

FIG. 15 depicts aspects of an example communications device.

### DETAILED DESCRIPTION

Aspects of the present disclosure relate to wireless communications, and more particularly, to techniques for indicating a version of system information (SI).

System information (SI) generally refers to details about a cellular network that are broadcast to user devices to enable them to access the network. A certain amount of SI is broadcast in what is referred to as a master information block (MIB). SI may include information, such as cell tower identification, frequency bands, and modulation schemes. Additional information, referred to as remaining minimum SI (RMSI) refers to certain additional information a wireless device needs to initially access the network and begin communicating therein. For example, RMSI may include information to identify the appropriate search space for other system information blocks (SIBs).

A MIB is periodically broadcast, via a broadcast channel (PBCH), as part of a synchronization signal block (SSB). RMSI is conveyed in a SIB (referred to as SIB1) via a physical downlink shared channel (PDSCH) scheduled by a physical downlink control channel (PDCCH).

RMSI content typically does not change very frequently and is relatively static not only over time but also over different locations (e.g., different gNBs, cells, physical cell identifiers-PCIs). As a result, in the event that a user equipment (UE) is unable to decode RMSI (e.g., due to poor channel conditions), the UE may be able to utilize previously decoded RMSI. Thus, instead of repeating the RMSI PDSCH (which increases network energy/power consumption as well as resources), an old RMSI that has been decoded when UE was at a different location (e.g., closer to the cell) before or when UE was in the coverage of a different cell before. One potential challenge with using previously decoded RMSI is how to indicate that a new version of RMSI is available (e.g., rendering the previously decoded version obsolete).

Aspects of the present disclosure, provide various signaling mechanisms for indicating versions of upcoming RMSI transmissions. For example, the version of an upcoming RMSI transmission may be indicated via a PDCCH scheduling a PDSCH conveying the RMSI (referred to as an RMSI PDCCH), a non-scheduling PDCCH, or a PDSCH that occurs before a PDSCH conveying the RMSI (referred to as a pre-RMSI PDSCH).

One potential benefit of the signaling mechanisms proposed herein is that, if the version of the upcoming RMSI matches the version of a previously decoded RMSI, the UE may skip decoding the upcoming RMSI PDSCH. Further, a match in versions may give the UE some assurance it may rely on previously decoded RMSI, which may be beneficial when the UE is in an area with limited coverage.

### Introduction to Wireless Communications Networks

The techniques and methods described herein may be used for various wireless communications networks. While aspects may be described herein using terminology commonly associated with 3G, 4G, and/or 5G wireless technologies, aspects of the present disclosure may likewise be applicable to other communications systems and standards not explicitly mentioned herein.

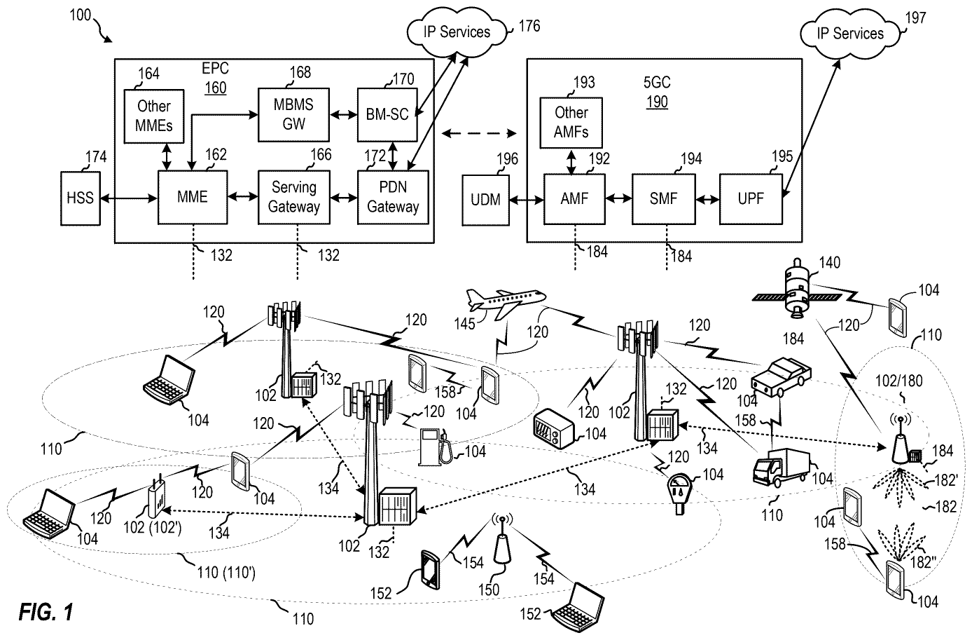

FIG. 1 depicts an example of a wireless communications network 100, in which aspects described herein may be implemented.

Generally, wireless communications network 100 includes various network entities (alternatively, network elements or network nodes). A network entity is generally a communications device and/or a communications function performed by a communications device (e.g., a user equipment (UE), a base station (BS), a component of a BS, a server, etc.). For example, various functions of a network as well as various devices associated with and interacting with a network may be considered network entities. Further, wireless communications network 100 includes terrestrial aspects, such as ground-based network entities (e.g., BSs 102), and non-terrestrial aspects, such as satellite 140 and aircraft 145, which may include network entities on-board (e.g., one or more BSs) capable of communicating with other network elements (e.g., terrestrial BSs) and user equipments.

In the depicted example, wireless communications network 100 includes BSs 102, UEs 104, and one or more core networks, such as an Evolved Packet Core (EPC) 160 and 5G Core (5GC) network 190, which interoperate to provide communications services over various communications links, including wired and wireless links.

FIG. 1 depicts various example UEs 104, which may more generally include: a cellular phone, smart phone, session initiation protocol (SIP) phone, laptop, personal digital assistant (PDA), satellite radio, global positioning system, multimedia device, video device, digital audio player, camera, game console, tablet, smart device, wearable device, vehicle, electric meter, gas pump, large or small kitchen appliance, healthcare device, implant, sensor/actuator, display, internet of things (IoT) devices, always on (AON) devices, edge processing devices, or other similar devices. UEs 104 may also be referred to more generally as a mobile device, a wireless device, a wireless communications device, a station, a mobile station, a subscriber station, a mobile subscriber station, a mobile unit, a subscriber unit, a wireless unit, a remote unit, a remote device, an access terminal, a mobile terminal, a wireless terminal, a remote terminal, a handset, and others.

BSs 102 wirelessly communicate with (e.g., transmit signals to or receive signals from) UEs 104 via communications links 120. The communications links 120 between BSs 102 and UEs 104 may include uplink (UL) (also referred to as reverse link) transmissions from a UE 104 to a BS 102 and/or downlink (DL) (also referred to as forward link) transmissions from a BS 102 to a UE 104. The communications links 120 may use multiple-input and multiple-output (MIMO) antenna technology, including spatial multiplexing, beamforming, and/or transmit diversity in various aspects.

BSs 102 may generally include: a NodeB, enhanced NodeB (eNB), next generation enhanced NodeB (ng-eNB), next generation NodeB (gNB or gNodeB), access point, base transceiver station, radio base station, radio transceiver, transceiver function, transmission reception point, and/or others. Each of BSs 102 may provide communications coverage for a respective geographic coverage area 110, which may sometimes be referred to as a cell, and which may overlap in some cases (e.g., small cell 102′ may have a coverage area 110′ that overlaps the coverage area 110 of a macro cell). A BS may, for example, provide communications coverage for a macro cell (covering relatively large geographic area), a pico cell (covering relatively smaller geographic area, such as a sports stadium), a femto cell (relatively smaller geographic area (e.g., a home)), and/or other types of cells.

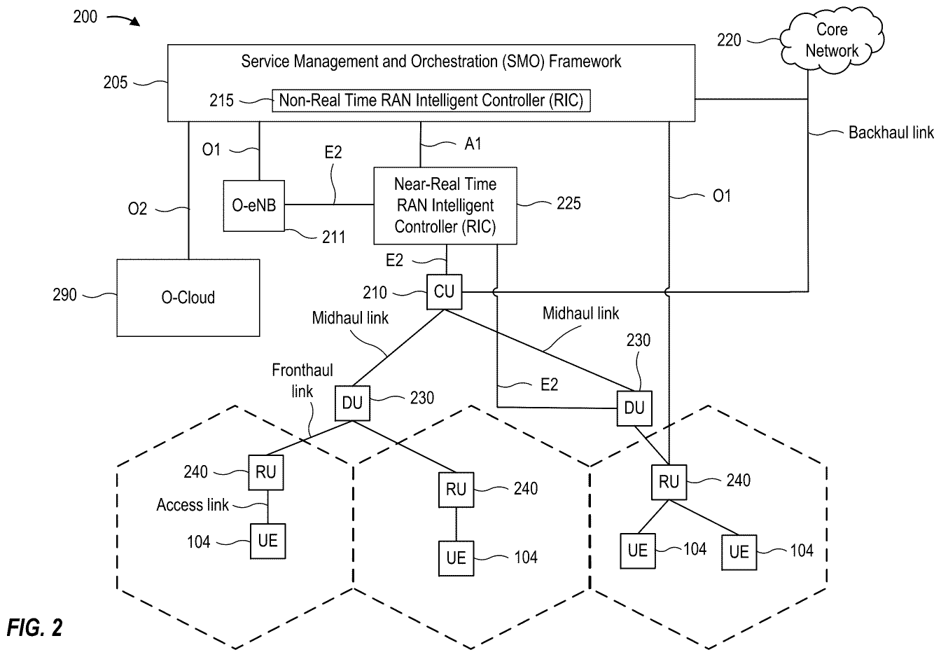

While BSs 102 are depicted in various aspects as unitary communications devices, BSs 102 may be implemented in various configurations. For example, one or more components of a base station may be disaggregated, including a central unit (CU), one or more distributed units (DUs), one or more radio units (RUs), a Near-Real Time (Near-RT) RAN Intelligent Controller (RIC), or a Non-Real Time (Non-RT) RIC, to name a few examples. In another example, various aspects of a base station may be virtualized. More generally, a base station (e.g., BS 102) may include components that are located at a single physical location or components located at various physical locations. In examples in which a base station includes components that are located at various physical locations, the various components may each perform functions such that, collectively, the various components achieve functionality that is similar to a base station that is located at a single physical location. In some aspects, a base station including components that are located at various physical locations may be referred to as a disaggregated radio access network architecture, such as an Open RAN (O-RAN) or Virtualized RAN (VRAN) architecture. FIG. 2 depicts and describes an example disaggregated base station architecture.

Different BSs 102 within wireless communications network 100 may also be configured to support different radio access technologies, such as 3G, 4G, and/or 5G. For example, BSs 102 configured for 4G LTE (collectively referred to as Evolved Universal Mobile Telecommunications System (UMTS) Terrestrial Radio Access Network (E-UTRAN)) may interface with the EPC 160 through first backhaul links 132 (e.g., an S1 interface). BSs 102 configured for 5G (e.g., 5G NR or Next Generation RAN (NG-RAN)) may interface with 5GC 190 through second backhaul links 184. BSs 102 may communicate directly or indirectly (e.g., through the EPC 160 or 5GC 190) with each other over third backhaul links 134 (e.g., X2 interface), which may be wired or wireless.

Wireless communications network 100 may subdivide the electromagnetic spectrum into various classes, bands, channels, or other features. In some aspects, the subdivision is provided based on wavelength and frequency, where frequency may also be referred to as a carrier, a subcarrier, a frequency channel, a tone, or a subband. For example, 3GPP currently defines Frequency Range 1 (FR1) as including 410 MHz-7125 MHz, which is often referred to (interchangeably) as “Sub-6 GHz”. Similarly, 3GPP currently defines Frequency Range 2 (FR2) as including 24,250 MHz-71,000 MHz, which is sometimes referred to (interchangeably) as a “millimeter wave” (“mmW” or “mmWave”). In some cases, FR2 may be further defined in terms of sub-ranges, such as a first sub-range FR2-1 including 24,250 MHz-52,600 MHz and a second sub-range FR2-2 including 52,600 MHz-71,000 MHz. A base station configured to communicate using mm Wave/near mmWave radio frequency bands (e.g., a mmWave base station such as BS 180) may utilize beamforming (e.g., 182) with a UE (e.g., 104) to improve path loss and range.

The communications links 120 between BSs 102 and, for example, UEs 104, may be through one or more carriers, which may have different bandwidths (e.g., 5, 10, 15, 20, 100, 400, and/or other MHz), and which may be aggregated in various aspects. Carriers may or may not be adjacent to each other. Allocation of carriers may be asymmetric with respect to DL and UL (e.g., more or fewer carriers may be allocated for DL than for UL).

Communications using higher frequency bands may have higher path loss and a shorter range compared to lower frequency communications. Accordingly, certain base stations (e.g., 180 in FIG. 1) may utilize beamforming 182 with a UE 104 to improve path loss and range. For example, BS 180 and the UE 104 may each include a plurality of antennas, such as antenna elements, antenna panels, and/or antenna arrays to facilitate the beamforming. In some cases, BS 180 may transmit a beamformed signal to UE 104 in one or more transmit directions 182′. UE 104 may receive the beamformed signal from the BS 180 in one or more receive directions 182″. UE 104 may also transmit a beamformed signal to the BS 180 in one or more transmit directions 182″. BS 180 may also receive the beamformed signal from UE 104 in one or more receive directions 182′ BS 180 and UE 104 may then perform beam training to determine the best receive and transmit directions for each of BS 180 and UE 104. Notably, the transmit and receive directions for BS 180 may or may not be the same. Similarly, the transmit and receive directions for UE 104 may or may not be the same.

Wireless communications network 100 further includes a Wi-Fi AP 150 in communication with Wi-Fi stations (STAs) 152 via communications links 154 in, for example, a 2.4 GHz and/or 5 GHz unlicensed frequency spectrum.

Certain UEs 104 may communicate with each other using device-to-device (D2D) communications link 158. D2D communications link 158 may use one or more sidelink channels, such as a physical sidelink broadcast channel (PSBCH), a physical sidelink discovery channel (PSDCH), a physical sidelink shared channel (PSSCH), a physical sidelink control channel (PSCCH), and/or a physical sidelink feedback channel (PSFCH).

EPC 160 may include various functional components, including: a Mobility Management Entity (MME) 162, other MMEs 164, a Serving Gateway 166, a Multimedia Broadcast Multicast Service (MBMS) Gateway 168, a Broadcast Multicast Service Center (BM-SC) 170, and/or a Packet Data Network (PDN) Gateway 172, such as in the depicted example. MME 162 may be in communication with a Home Subscriber Server (HSS) 174. MME 162 is the control node that processes the signaling between the UEs 104 and the EPC 160. Generally, MME 162 provides bearer and connection management.

Generally, user Internet protocol (IP) packets are transferred through Serving Gateway 166, which itself is connected to PDN Gateway 172. PDN Gateway 172 provides UE IP address allocation as well as other functions. PDN Gateway 172 and the BM-SC 170 are connected to IP Services 176, which may include, for example, the Internet, an intranet, an IP Multimedia Subsystem (IMS), a Packet Switched (PS) streaming service, and/or other IP services.

BM-SC 170 may provide functions for MBMS user service provisioning and delivery. BM-SC 170 may serve as an entry point for content provider MBMS transmission, may be used to authorize and initiate MBMS Bearer Services within a public land mobile network (PLMN), and/or may be used to schedule MBMS transmissions. MBMS Gateway 168 may be used to distribute MBMS traffic to the BSs 102 belonging to a Multicast Broadcast Single Frequency Network (MBSFN) area broadcasting a particular service, and/or may be responsible for session management (start/stop) and for collecting eMBMS related charging information.

5GC 190 may include various functional components, including: an Access and Mobility Management Function (AMF) 192, other AMFs 193, a Session Management Function (SMF) 194, and a User Plane Function (UPF) 195. AMF 192 may be in communication with Unified Data Management (UDM) 196.

AMF 192 is a control node that processes signaling between UEs 104 and 5GC 190. AMF 192 provides, for example, quality of service (QoS) flow and session management.

Internet protocol (IP) packets are transferred through UPF 195, which is connected to the IP Services 197, and which provides UE IP address allocation as well as other functions for 5GC 190. IP Services 197 may include, for example, the Internet, an intranet, an IMS, a PS streaming service, and/or other IP services.

In various aspects, a network entity or network node can be implemented as an aggregated base station, as a disaggregated base station, a component of a base station, an integrated access and backhaul (IAB) node, a relay node, a sidelink node, to name a few examples.

FIG. 2 depicts an example disaggregated base station 200 architecture. The disaggregated base station 200 architecture may include one or more central units (CUs) 210 that can communicate directly with a core network 220 via a backhaul link, or indirectly with the core network 220 through one or more disaggregated base station units (such as a Near-Real Time (Near-RT) RAN Intelligent Controller (RIC) 225 via an E2 link, or a Non-Real Time (Non-RT) RIC 215 associated with a Service Management and Orchestration (SMO) Framework 205, or both). A CU 210 may communicate with one or more distributed units (DUs) 230 via respective midhaul links, such as an F1 interface. The DUs 230 may communicate with one or more radio units (RUs) 240 via respective fronthaul links. The RUs 240 may communicate with respective UEs 104 via one or more radio frequency (RF) access links. In some implementations, the UE 104 may be simultaneously served by multiple RUs 240.

Each of the units, e.g., the CUS 210, the DUs 230, the RUs 240, as well as the Near-RT RICs 225, the Non-RT RICs 215 and the SMO Framework 205, may include one or more interfaces or be coupled to one or more interfaces configured to receive or transmit signals, data, or information (collectively, signals) via a wired or wireless transmission medium. Each of the units, or an associated processor or controller providing instructions to the communications interfaces of the units, can be configured to communicate with one or more of the other units via the transmission medium. For example, the units can include a wired interface configured to receive or transmit signals over a wired transmission medium to one or more of the other units. Additionally or alternatively, the units can include a wireless interface, which may include a receiver, a transmitter or transceiver (such as a radio frequency (RF) transceiver), configured to receive or transmit signals, or both, over a wireless transmission medium to one or more of the other units.

In some aspects, the CU 210 may host one or more higher layer control functions. Such control functions can include radio resource control (RRC), packet data convergence protocol (PDCP), service data adaptation protocol (SDAP), or the like. Each control function can be implemented with an interface configured to communicate signals with other control functions hosted by the CU 210. The CU 210 may be configured to handle user plane functionality (e.g., Central Unit-User Plane (CU-UP)), control plane functionality (e.g., Central Unit-Control Plane (CU-CP)), or a combination thereof. In some implementations, the CU 210 can be logically split into one or more CU-UP units and one or more CU-CP units. The CU-UP unit can communicate bidirectionally with the CU-CP unit via an interface, such as the E1 interface when implemented in an O-RAN configuration. The CU 210 can be implemented to communicate with the DU 230, as necessary, for network control and signaling.

The DU 230 may correspond to a logical unit that includes one or more base station functions to control the operation of one or more RUs 240. In some aspects, the DU 230 may host one or more of a radio link control (RLC) layer, a medium access control (MAC) layer, and one or more high physical (PHY) layers (such as modules for forward error correction (FEC) encoding and decoding, scrambling, modulation and demodulation, or the like) depending, at least in part, on a functional split, such as those defined by the 3^{rd} Generation Partnership Project (3GPP). In some aspects, the DU 230 may further host one or more low PHY layers. Each layer (or module) can be implemented with an interface configured to communicate signals with other layers (and modules) hosted by the DU 230, or with the control functions hosted by the CU 210.

Lower-layer functionality can be implemented by one or more RUs 240. In some deployments, an RU 240, controlled by a DU 230, may correspond to a logical node that hosts RF processing functions, or low-PHY layer functions (such as performing fast Fourier transform (FFT), inverse FFT (iFFT), digital beamforming, physical random access channel (PRACH) extraction and filtering, or the like), or both, based at least in part on the functional split, such as a lower layer functional split. In such an architecture, the RU(s) 240 can be implemented to handle over the air (OTA) communications with one or more UEs 104. In some implementations, real-time and non-real-time aspects of control and user plane communications with the RU(s) 240 can be controlled by the corresponding DU 230. In some scenarios, this configuration can enable the DU(s) 230 and the CU 210 to be implemented in a cloud-based RAN architecture, such as a vRAN architecture.

The SMO Framework 205 may be configured to support RAN deployment and provisioning of non-virtualized and virtualized network elements. For non-virtualized network elements, the SMO Framework 205 may be configured to support the deployment of dedicated physical resources for RAN coverage requirements which may be managed via an operations and maintenance interface (such as an O1 interface). For virtualized network elements, the SMO Framework 205 may be configured to interact with a cloud computing platform (such as an open cloud (O-Cloud) 290) to perform network element life cycle management (such as to instantiate virtualized network elements) via a cloud computing platform interface (such as an O2 interface). Such virtualized network elements can include, but are not limited to, CUs 210, DUs 230, RUs 240 and Near-RT RICs 225. In some implementations, the SMO Framework 205 can communicate with a hardware aspect of a 4G RAN, such as an open eNB (O-eNB) 211, via an O1 interface. Additionally, in some implementations, the SMO Framework 205 can communicate directly with one or more RUs 240 via an O1 interface. The SMO Framework 205 also may include a Non-RT RIC 215 configured to support functionality of the SMO Framework 205.

The Non-RT RIC 215 may be configured to include a logical function that enables non-real-time control and optimization of RAN elements and resources, Artificial Intelligence/Machine Learning (AI/ML) workflows including model training and updates, or policy-based guidance of applications/features in the Near-RT RIC 225. The Non-RT RIC 215 may be coupled to or communicate with (such as via an A1 interface) the Near-RT RIC 225. The Near-RT RIC 225 may be configured to include a logical function that enables near-real-time control and optimization of RAN elements and resources via data collection and actions over an interface (such as via an E2 interface) connecting one or more CUs 210, one or more DUs 230, or both, as well as an O-eNB, with the Near-RT RIC 225.

In some implementations, to generate AI/ML models to be deployed in the Near-RT RIC 225, the Non-RT RIC 215 may receive parameters or external enrichment information from external servers. Such information may be utilized by the Near-RT RIC 225 and may be received at the SMO Framework 205 or the Non-RT RIC 215 from non-network data sources or from network functions. In some examples, the Non-RT RIC 215 or the Near-RT RIC 225 may be configured to tune RAN behavior or performance. For example, the Non-RT RIC 215 may monitor long-term trends and patterns for performance and employ AI/ML models to perform corrective actions through the SMO Framework 205 (such as reconfiguration via O1) or via creation of RAN management policies (such as A1 policies).

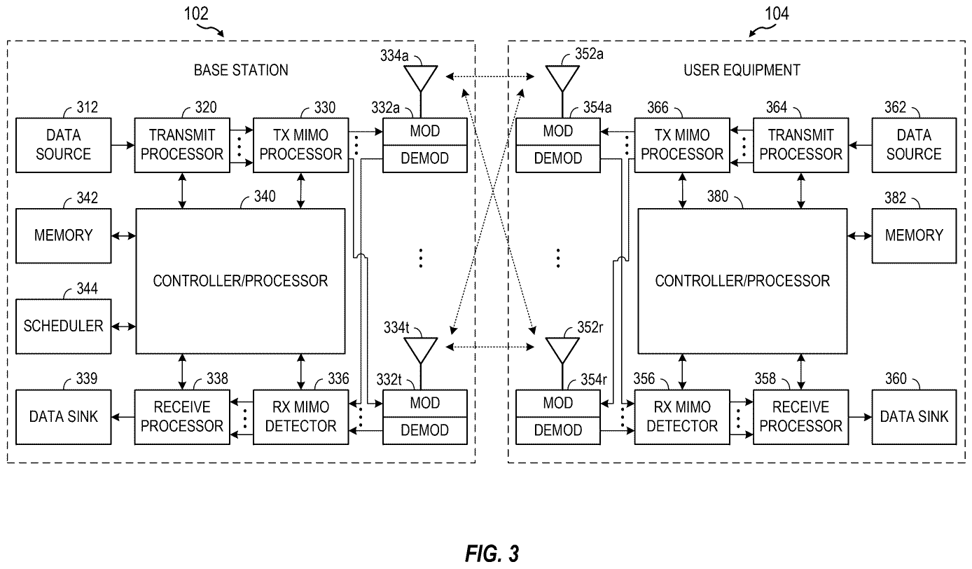

FIG. 3 depicts aspects of an example BS 102 and a UE 104.

Generally, BS 102 includes various processors (e.g., 320, 330, 338, and 340), antennas 334a-t (collectively 334), transceivers 332a-t (collectively 332), which include modulators and demodulators, and other aspects, which enable wireless transmission of data (e.g., data source 312) and wireless reception of data (e.g., data sink 339). For example, BS 102 may send and receive data between BS 102 and UE 104. BS 102 includes controller/processor 340, which may be configured to implement various functions described herein related to wireless communications.

Generally, UE 104 includes various processors (e.g., 358, 364, 366, and 380), antennas 352a-r (collectively 352), transceivers 354a-r (collectively 354), which include modulators and demodulators, and other aspects, which enable wireless transmission of data (e.g., retrieved from data source 362) and wireless reception of data (e.g., provided to data sink 360). UE 104 includes controller/processor 380, which may be configured to implement various functions described herein related to wireless communications.

In regards to an example downlink transmission, BS 102 includes a transmit processor 320 that may receive data from a data source 312 and control information from a controller/processor 340. The control information may be for the physical broadcast channel (PBCH), physical control format indicator channel (PCFICH), physical HARQ indicator channel (PHICH), physical downlink control channel (PDCCH), group common PDCCH (GC PDCCH), and/or others. The data may be for the physical downlink shared channel (PDSCH), in some examples.

Transmit processor 320 may process (e.g., encode and symbol map) the data and control information to obtain data symbols and control symbols, respectively. Transmit processor 320 may also generate reference symbols, such as for the primary synchronization signal (PSS), secondary synchronization signal (SSS), PBCH demodulation reference signal (DMRS), and channel state information reference signal (CSI-RS).

Transmit (TX) multiple-input multiple-output (MIMO) processor 330 may perform spatial processing (e.g., precoding) on the data symbols, the control symbols, and/or the reference symbols, if applicable, and may provide output symbol streams to the modulators (MODs) in transceivers 332a-332t. Each modulator in transceivers 332a-332t may process a respective output symbol stream to obtain an output sample stream. Each modulator may further process (e.g., convert to analog, amplify, filter, and upconvert) the output sample stream to obtain a downlink signal. Downlink signals from the modulators in transceivers 332a-332t may be transmitted via the antennas 334a-334t, respectively.

In order to receive the downlink transmission, UE 104 includes antennas 352a-352r that may receive the downlink signals from the BS 102 and may provide received signals to the demodulators (DEMODs) in transceivers 354a-354r, respectively. Each demodulator in transceivers 354a-354r may condition (e.g., filter, amplify, downconvert, and digitize) a respective received signal to obtain input samples. Each demodulator may further process the input samples to obtain received symbols.

MIMO detector 356 may obtain received symbols from all the demodulators in transceivers 354a-354r, perform MIMO detection on the received symbols if applicable, and provide detected symbols. Receive processor 358 may process (e.g., demodulate, deinterleave, and decode) the detected symbols, provide decoded data for the UE 104 to a data sink 360, and provide decoded control information to a controller/processor 380.

In regards to an example uplink transmission, UE 104 further includes a transmit processor 364 that may receive and process data (e.g., for the PUSCH) from a data source 362 and control information (e.g., for the physical uplink control channel (PUCCH)) from the controller/processor 380. Transmit processor 364 may also generate reference symbols for a reference signal (e.g., for the sounding reference signal (SRS)). The symbols from the transmit processor 364 may be precoded by a TX MIMO processor 366 if applicable, further processed by the modulators in transceivers 354a-354r (e.g., for SC-FDM), and transmitted to BS 102.

At BS 102, the uplink signals from UE 104 may be received by antennas 334a-t, processed by the demodulators in transceivers 332a-332t, detected by a MIMO detector 336 if applicable, and further processed by a receive processor 338 to obtain decoded data and control information sent by UE 104. Receive processor 338 may provide the decoded data to a data sink 339 and the decoded control information to the controller/processor 340.

Memories 342 and 382 may store data and program codes for BS 102 and UE 104, respectively.

Scheduler 344 may schedule UEs for data transmission on the downlink and/or uplink.

In various aspects, BS 102 may be described as transmitting and receiving various types of data associated with the methods described herein. In these contexts, “transmitting” may refer to various mechanisms of outputting data, such as outputting data from data source 312, scheduler 344, memory 342, transmit processor 320, controller/processor 340, TX MIMO processor 330, transceivers 332a-t, antenna 334a-t, and/or other aspects described herein. Similarly, “receiving” may refer to various mechanisms of obtaining data, such as obtaining data from antennas 334a-t, transceivers 332a-t, RX MIMO detector 336, controller/processor 340, receive processor 338, scheduler 344, memory 342, and/or other aspects described herein.

In various aspects, UE 104 may likewise be described as transmitting and receiving various types of data associated with the methods described herein. In these contexts, “transmitting” may refer to various mechanisms of outputting data, such as outputting data from data source 362, memory 382, transmit processor 364, controller/processor 380, TX MIMO processor 366, transceivers 354a-t, antenna 352a-t, and/or other aspects described herein. Similarly, “receiving” may refer to various mechanisms of obtaining data, such as obtaining data from antennas 352a-t, transceivers 354a-t, RX MIMO detector 356, controller/processor 380, receive processor 358, memory 382, and/or other aspects described herein.

In some aspects, one or more processors may be configured to perform various operations, such as those associated with the methods described herein, and transmit (output) to or receive (obtain) data from another interface that is configured to transmit or receive, respectively, the data.

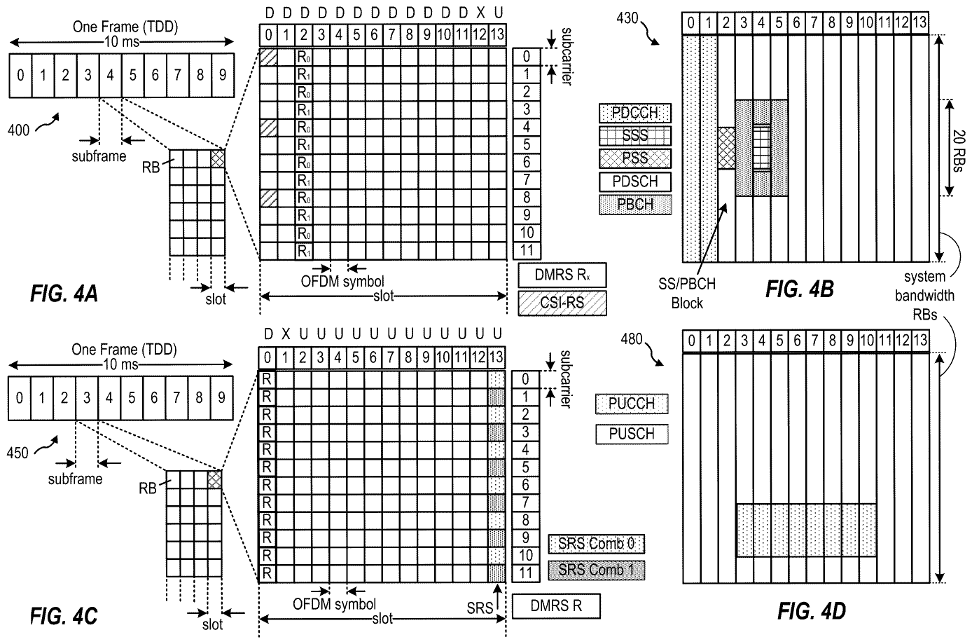

FIGS. 4A, 4B, 4C, and 4D depict aspects of data structures for a wireless communications network, such as wireless communications network 100 of FIG. 1.

In particular, FIG. 4A is a diagram 400 illustrating an example of a first subframe within a 5G (e.g., 5G NR) frame structure, FIG. 4B is a diagram 430 illustrating an example of DL channels within a 5G subframe, FIG. 4C is a diagram 450 illustrating an example of a second subframe within a 5G frame structure, and FIG. 4D is a diagram 480 illustrating an example of UL channels within a 5G subframe.

Wireless communications systems may utilize orthogonal frequency division multiplexing (OFDM) with a cyclic prefix (CP) on the uplink and downlink. Such systems may also support half-duplex operation using time division duplexing (TDD). OFDM and single-carrier frequency division multiplexing (SC-FDM) partition the system bandwidth (e.g., as depicted in FIGS. 4B and 4D) into multiple orthogonal subcarriers. Each subcarrier may be modulated with data. Modulation symbols may be sent in the frequency domain with OFDM and/or in the time domain with SC-FDM.

A wireless communications frame structure may be frequency division duplex (FDD), in which, for a particular set of subcarriers, subframes within the set of subcarriers are dedicated for either DL or UL. Wireless communications frame structures may also be time division duplex (TDD), in which, for a particular set of subcarriers, subframes within the set of subcarriers are dedicated for both DL and UL.

In FIGS. 4A and 4C, the wireless communications frame structure is TDD where D is DL, U is UL, and X is flexible for use between DL/UL. UEs may be configured with a slot format through a received slot format indicator (SFI) (dynamically through DL control information (DCI), or semi-statically/statically through radio resource control (RRC) signaling). In the depicted examples, a 10 ms frame is divided into 10 equally sized 1 ms subframes. Each subframe may include one or more time slots. In some examples, each slot may include 7 or 14 symbols, depending on the slot format. Subframes may also include mini-slots, which generally have fewer symbols than an entire slot. Other wireless communications technologies may have a different frame structure and/or different channels.

In certain aspects, the number of slots within a subframe is based on a slot configuration and a numerology. For example, for slot configuration 0, different numerologies (μ) 0 to 6 allow for 1, 2, 4, 8, 16, 32, and 64 slots, respectively, per subframe. For slot configuration 1, different numerologies 0 to 2 allow for 2, 4, and 8 slots, respectively, per subframe. Accordingly, for slot configuration 0 and numerology μ, there are 14 symbols/slot and 2μ slots/subframe. The subcarrier spacing and symbol length/duration are a function of the numerology. The subcarrier spacing may be equal to 24×15 kHz, where μ is the numerology 0 to 6. As such, the numerology μ=0 has a subcarrier spacing of 15 kHz and the numerology μ=6 has a subcarrier spacing of 960 kHz. The symbol length/duration is inversely related to the subcarrier spacing. FIGS. 4A, 4B, 4C, and 4D provide an example of slot configuration 0 with 14 symbols per slot and numerology μ=2 with 4 slots per subframe. The slot duration is 0.25 ms, the subcarrier spacing is 60 kHz, and the symbol duration is approximately 16.67 μs.

As depicted in FIGS. 4A, 4B, 4C, and 4D, a resource grid may be used to represent the frame structure. Each time slot includes a resource block (RB) (also referred to as physical RBs (PRBs)) that extends, for example, 12 consecutive subcarriers. The resource grid is divided into multiple resource elements (REs). The number of bits carried by each RE depends on the modulation scheme.

As illustrated in FIG. 4A, some of the REs carry reference (pilot) signals (RS) for a UE (e.g., UE 104 of FIGS. 1 and 3). The RS may include demodulation RS (DMRS) and/or channel state information reference signals (CSI-RS) for channel estimation at the UE. The RS may also include beam measurement RS (BRS), beam refinement RS (BRRS), and/or phase tracking RS (PT-RS).

FIG. 4B illustrates an example of various DL channels within a subframe of a frame. The physical downlink control channel (PDCCH) carries DCI within one or more control channel elements (CCEs), each CCE including, for example, nine RE groups (REGs), each REG including, for example, four consecutive REs in an OFDM symbol.

A primary synchronization signal (PSS) may be within symbol 2 of particular subframes of a frame. The PSS is used by a UE (e.g., 104 of FIGS. 1 and 3) to determine subframe/symbol timing and a physical layer identity.

A secondary synchronization signal (SSS) may be within symbol 4 of particular subframes of a frame. The SSS is used by a UE to determine a physical layer cell identity group number and radio frame timing.

Based on the physical layer identity and the physical layer cell identity group number, the UE can determine a physical cell identifier (PCI). Based on the PCI, the UE can determine the locations of the aforementioned DMRS. The physical broadcast channel (PBCH), which carries a master information block (MIB), may be logically grouped with the PSS and SSS to form a synchronization signal (SS)/PBCH block. The MIB provides a number of RBs in the system bandwidth and a system frame number (SFN). The physical downlink shared channel (PDSCH) carries user data, broadcast system information not transmitted through the PBCH such as system information blocks (SIBs), and/or paging messages.

As illustrated in FIG. 4C, some of the REs carry DMRS (indicated as R for one particular configuration, but other DMRS configurations are possible) for channel estimation at the base station. The UE may transmit DMRS for the PUCCH and DMRS for the PUSCH. The PUSCH DMRS may be transmitted, for example, in the first one or two symbols of the PUSCH. The PUCCH DMRS may be transmitted in different configurations depending on whether short or long PUCCHs are transmitted and depending on the particular PUCCH format used. UE 104 may transmit sounding reference signals (SRS). The SRS may be transmitted, for example, in the last symbol of a subframe. The SRS may have a comb structure, and a UE may transmit SRS on one of the combs. The SRS may be used by a base station for channel quality estimation to enable frequency-dependent scheduling on the UL.

FIG. 4D illustrates an example of various UL channels within a subframe of a frame. The PUCCH may be located as indicated in one configuration. The PUCCH carries uplink control information (UCI), such as scheduling requests, a channel quality indicator (CQI), a precoding matrix indicator (PMI), a rank indicator (RI), and HARQ ACK/NACK feedback. The PUSCH carries data, and may additionally be used to carry a buffer status report (BSR), a power headroom report (PHR), and/or UCI.

### Overview of System Information

System information (SI) generally refers to details about a cellular network that are broadcast to user devices to enable them to access the network. A certain amount of SI is broadcast in what is referred to as a master information block (MIB). SI may include information, such as cell tower identification, frequency bands, and modulation schemes. Additional information, referred to as remaining minimum SI (RMSI) refers to certain additional information a wireless device needs to initially access the network and begin communicating therein. For example, RMSI may include information to identify the appropriate search space for other system information blocks (SIBs).

A MIB is periodically broadcast, via a broadcast channel (PBCH), as part of a synchronization signal block (SSB). RMSI is conveyed in a SIB (referred to as SIB1) via a physical downlink shared channel (PDSCH) scheduled by a physical downlink control channel (PDCCH).

SIB1 (RMSI) conveyed via the PDSCH may be scheduled by the PDCCH associated with a common search space (CSS, e.g., the Type0-CSS). The SIB1 may be periodically broadcast (e.g., every 160 ms) with repetition (e.g., every 20 ms) with up to 8 repetitions within the 160 ms SIB1 periodicity. Other system information (OSI/SIB2-9) may be conveyed, for example, via a PDSCH scheduled by the PDCCH associated with a different CSS (e.g., the Type0A-CSS). In some cases, on-demand SI delivery may be available upon the UE request.

RMSI may be periodically broadcast according to one of a set of CORESET0/SSB multiplexing patterns. These patterns include a first pattern (pattern 1) that time division multiplexes (TDMs) the RMSI PDCCH/PDSCH with the SSB in FR1/FR2 and a second pattern (pattern 2) that TDMs and frequency division multiplexes (FDMs) the RMSI PDCCH/PDSCH with the SSB in FR2, and a third pattern (pattern 3) that FDMs the RMSI PDCCH/PDSCH with the SSB in FR2. DCI format 1_0 with the SI-RNTI monitored on Type0-CSS schedules the RMSI PDSCH

With pattern 2, for subcarrier spacings (SCSs) for SSBs and the RMSI PDCCH/PDSCH of 120 kHz and 60 kHz (respectively) there is a 1-symbol RMSI PDCCH and a 2-symbol RMSI PDSCH and for SCSs of 240 kHz (SSB) and 120 kHz (RMSI PDCCH/PDSCH) there is a 1-symbol RMSI PDCCH and a 2-symbol RMSI PDSCH. For pattern 3, with SSB SCS and RMSI PDCCH/PDSCH SCS of 120 kHz for each, there is a 2-symbol RMSI PDCCH and a 2-symbol RMSI PDSCH.

RMSI multiplexing patterns 2 and 3 may help reduce broadcast channel overhead due to analog beam constraint by FDMing SSB and RMSI PDCCH/PDSCH.

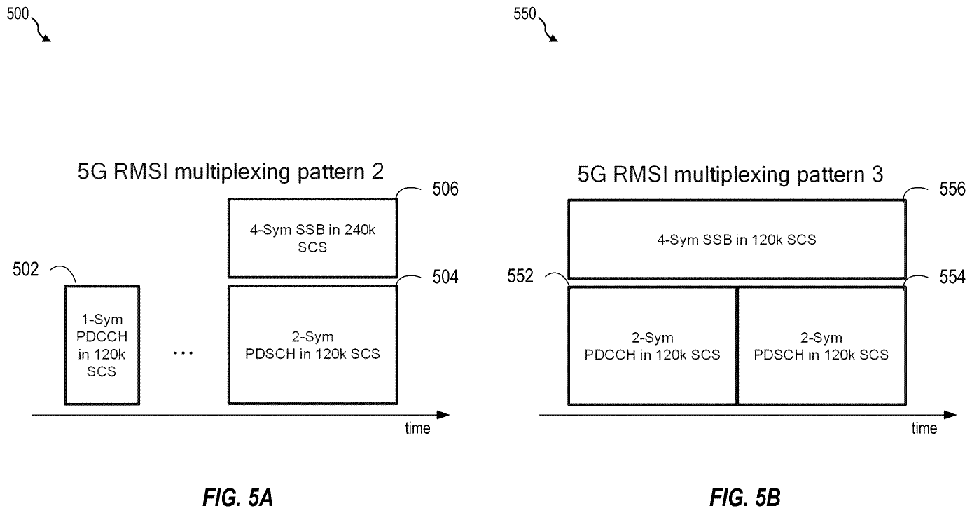

As illustrated in diagram 500 of FIG. 5A, for pattern 2, RMSI PDCCH 502 and RMSI PDSCH 504 only have 1 and 2 symbols, respectively. As illustrated, RMSI PDSCH 504 in 120 k SCS is FDMed with SSBs 506 in 240 k SCS, with 4 SSBs packed in each slot.

As illustrated in diagram 550 of FIG. 5B, for pattern 3, both RMSI PDCCH 552 and RMSI PDSCH 554 have 2 symbols and FDMed with SSB 556, all in 120 k SCS. As illustrated, 2 SSBs are packed in each slot.

With limited RMSI PDSCH symbols in multiplexing patterns 2 and 3, the coverage of RMSI PDSCH may be affected significantly. In other words, the coding rate of RMSI may be high and, hence, RMSI PDSCH may be a coverage bottleneck compared to other channels.

### Aspects Related to Pre-RMSI Version ID Indication

As noted above, RMSI content typically does not change very frequently and is relatively static not only over time but also over different locations. As a result, in the event that a user equipment (UE) is unable to decode RMSI, the UE may be able to utilize previously decoded RMSI. One potential challenge with using previously decoded RMSI is how to indicate that a new version of RMSI is available (e.g., rendering the previously decoded version obsolete).

According to aspects of the present disclosure, each version of RMSI may be associated with an RMSI version ID. Using a version ID, if a UE reads RMSI at a given time and from a given cell, and the RMSI does not change, when the UE arrives at a location that RMSI cannot be decoded, it can use the old RMSI (knowing it is the same based on a version ID).

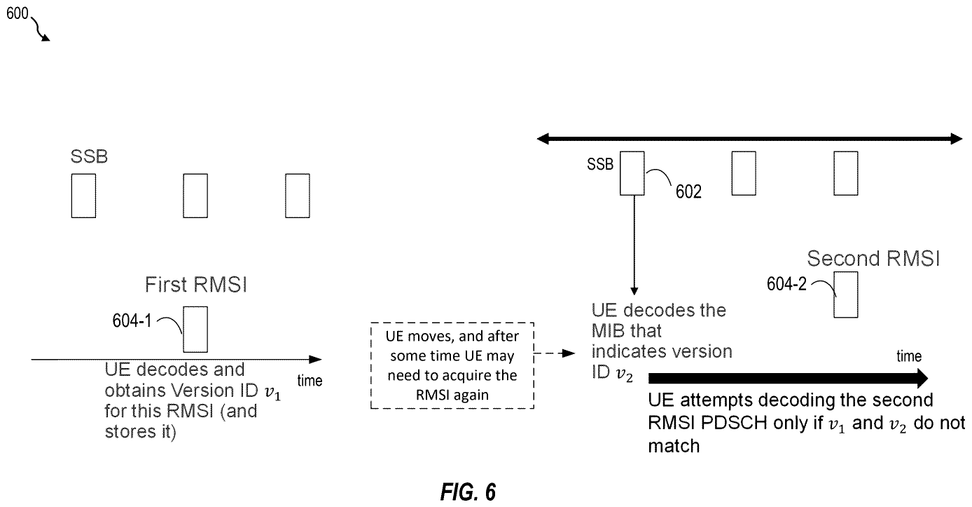

As illustrated in diagram 600 of FIG. 6, a version ID may be included in each RMSI and is associated with that RMSI payload (e.g., version ID v₁ is associated with the payload of a first RMSI 604-1). A UE may store multiple RMSIs with corresponding version IDs at different times/from different cells. In the illustrated example, the UE moves, and after some time UE may need to acquire the RMSI again.

As illustrated, a MIB/PBCH (conveyed in an SSB 602) may include an indication associated with the version ID (12) of a second RMSI 604-2 to be transmitted from this cell over a time window. As indicated, when version ID v₂ matches with a stored RMSI version ID v₁, the UE may use the stored RMSI (and can skip decoding RMSI 604-2). Otherwise, if version ID v₂ does not match with the stored RMSI version ID 121, the UE may attempt to decode the RMSI PDSCH.

Utilizing a version ID conveyed via a MIB may work fairly well when a total number of different RMSI configurations used by an infrastructure (in time and/or cell domain) is not too large. Unfortunately, the MIB payload is fairly small, and it may not be practical to add a “version ID” field.

Aspects of the present disclosure, provide alternative signaling mechanisms that utilize a physical downlink channel to convey the version ID. For example, as will be described in greater detail below, the version of an upcoming RMSI transmission may be indicated via a PDCCH scheduling a PDSCH conveying the RMSI (referred to as an RMSI PDCCH), a non-scheduling PDCCH, or a PDSCH that occurs before a PDSCH conveying the RMSI (referred to as a pre-RMSI PDSCH).

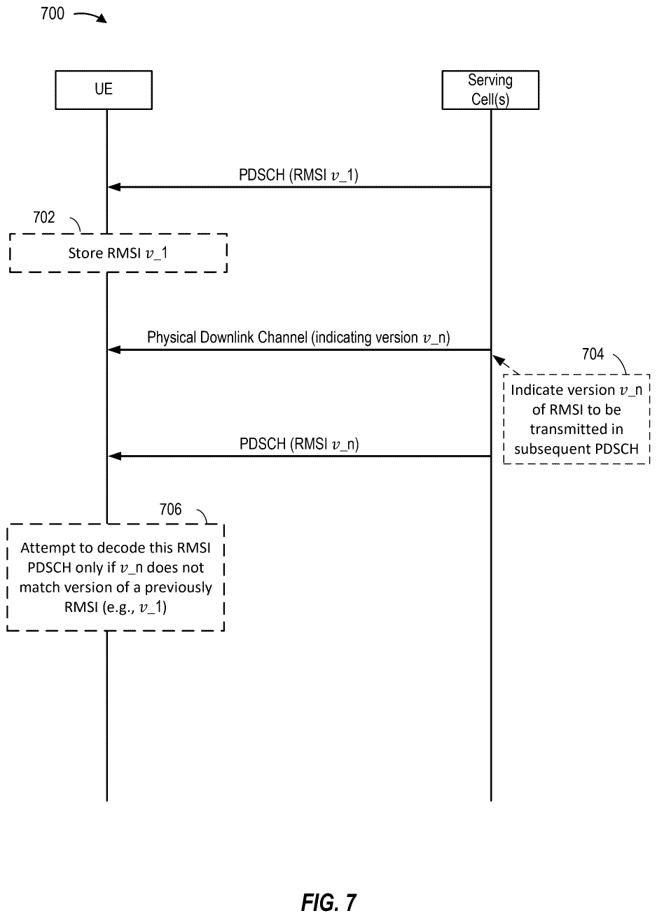

Pre-RMSI version indication proposed herein may be understood with reference to the call flow diagram 700 shown in FIG. 7.

In some aspects, the serving cell(s) shown in FIG. 7 may be an example of network entities, such as the BS depicted and described with respect to FIGS. 1 and 3 or a disaggregated base station depicted and described with respect to FIG. 2. Similarly, the UE shown in FIG. 7 may be an example of UE 104 depicted and described with respect to FIGS. 1 and 3. However, in other aspects, UE 104 may be another type of wireless communications device and BS 102 may be another type of network entity or network node, such as those described herein.

As indicated at 702, a UE may successfully decode a first version of RMSI (version ID=v₁). As indicated at 704, (a gNB of) a serving cell may indicate, in a physical downlink channel, a version ID (version ID=v) of RMSI to be conveyed in a subsequent PDSCH. As indicated at 706, the UE may attempt to decode this subsequent RMSI PDSCH only if (indicated in the physical downlink channel) does not match a version of a previously decoded RMSI (e.g., v₁).

According to certain aspects, the version ID (v) associated with a scheduled RMSI PDSCH may be conveyed in an RMSI PDCCH (e.g., the physical downlink channel shown in FIG. 7 may schedule the subsequent RMSI PDSCH). This approach may be utilized in different use cases.

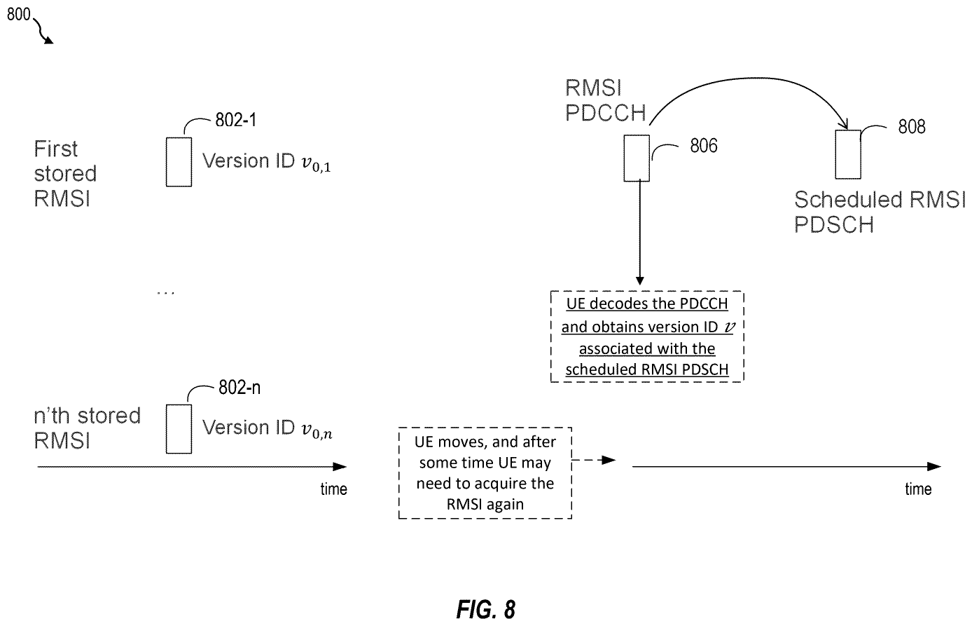

A first use case, depicted in diagram 800 FIG. 8, may assume that the UE has already stored one or more (successfully decoded) RMSI payloads (e.g., RMSI 802-1, RMSI 802-n) in memory. For example, it may be assumed that these stored RMSI payloads are associated with version IDs V₀={v_{0,1}, v_{0,2}, . . . , v_{0,n}}.

As illustrated, the UE may move and, after some time, the UE may need to acquire the RMSI again. The UE decodes the RMSI PDCCH 806 and obtains the version ID v associated with the scheduled RMSI PDSCH 808.

If the version ID v indicated in the RMSI PDCCH 806 matches the version ID of one of the stored RMSI payloads (e.g., any of the version IDs {v_{0,1}, v_{0,2}, . . . , v_{0,n}}), the UE can skip decoding the scheduled RMSI and use the corresponding stored RMSI payload instead. Otherwise, if there is no match, the UE attempts decoding the scheduled RMSI PDSCH 808.

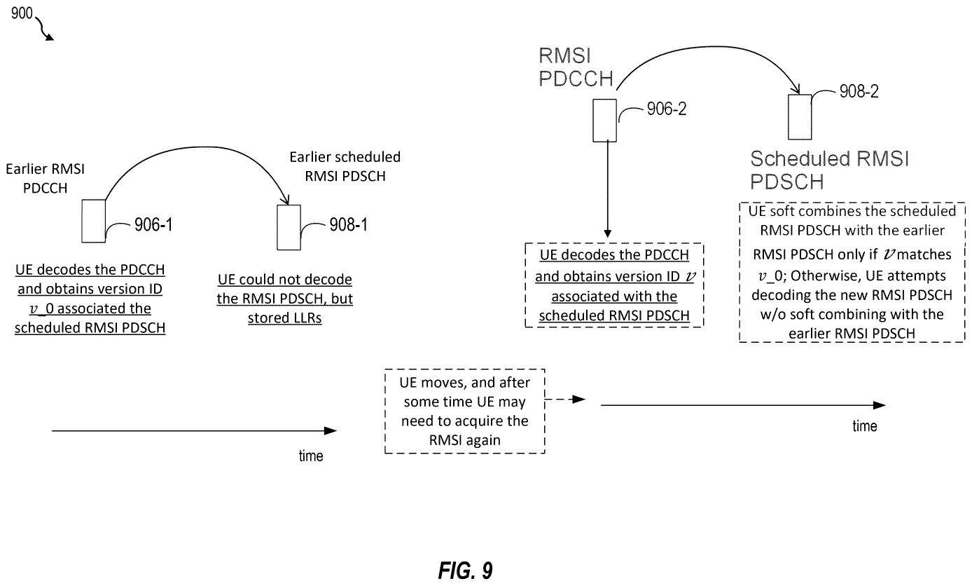

A second use case, depicted in diagram 900 of FIG. 9, assumes that the UE has decoded an earlier PDCCH RMSI 906-1 but could not decoded the corresponding RMSI PDSCH 908-1. As illustrated, the earlier PDCCH RMSI 906-1 indicated an RMSI version ID v₀. Thus, the UE decodes the PDCCH and obtains version ID v₀ associated the scheduled RMSI PDSCH, is unable to decode the RMSI PDSCH, but stored (as soft bits) the associated log-likelihood ratios (LLRs).

After moving, and sometime later, the UE decodes a subsequent RMSI PDCCH 906-2 and obtains the version ID v associated with the corresponding scheduled RMSI PDSCH 908-2. As illustrated, if v matches v₀, the UE may use the previously stored soft bits to perform soft combining when attempting to decode the scheduled RMSI PDSCH 908-2 (since both RMSI PDSCH 908-1 and RMSI PDSCH 908-2 contain the same transport block (TB) based on associated versions IDs matching). Otherwise, the UE may attempts decoding the new RMSI PDSCH 908-2 without soft combining. One potential advantage of this approach is that it may allow soft combining RMSI PDSCH beyond the typical RMSI periodicity (e.g., of 160 ms in NR).

According to certain aspects, the techniques described above with reference to the two use cases may be combined. For example, if there is a matching version ID associated with a stored RMSI payload, there may be no need to decode. However, if there is a matching version ID from the indicated version ID from earlier PDCCH RMSIs, with stored soft bits of RMSI PDSCH (but not decoded), the UE may perform soft combining and then attempt to decode. Otherwise, if no version match, the UE may attempt to decode without soft combining.

According to both use cases, the indication (of RMSI version) in DCI may be specific to a certain DCI format (e.g., DCI format 1_0) with a cyclic redundancy check (CRC) scrambled with a system information radio network temporary identifier (SI-RNTI). According to certain aspects, a UE may monitor for a PDCCH carrying such a DCI in Type0 CSS on a primary cell (PCell) of a master cell group (MCG). In some systems, there may be some number of reserved bits available for a version ID indication. For example, in NR, there may be up to 15 reserved bits in the DCI that is used to schedule PDSCH RMSI. These 15 bits (or a subset of them) can be used for indication of version ID v.

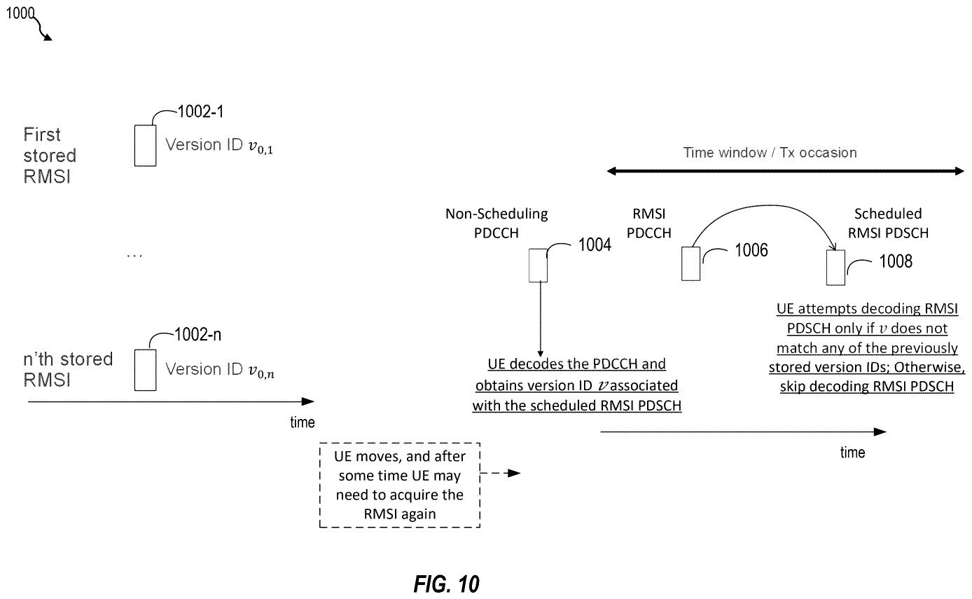

As illustrated in diagram 1000 of FIG. 10, a non-scheduling PDCCH 1004 (e.g., a PDCCH that does not schedule any PDSCH) may indicate a version ID (v) associated with RMSI payload in a time window. As illustrated, the RMSI payload (in an RMSI PDSCH 1008) in the time window may be scheduled by an RMSI PDCCH 1006 as normal (separate from this non-scheduling PDCCH 1004.)

According to certain aspects, the time window may be fixed. For example, the time window may be based on the RMSI period (e.g., 160 ms in NR) or multiple RMSI periods that includes this non-scheduling PDCCH. In some cases, the time window may be indicated by the non-scheduling PDCCH.

According to certain aspects, the non-scheduling PDCCH may be a DCI format 1_0 in CSS. The UE may distinguish between this DCI and an RMSI PDCCH (also a DCI format 1_0 in CSS) by either an explicit field in the DCI or based on the RNTI (CRC mask of the DCI).

The example illustrated in FIG. 10 assumes that the UE has already stored one or more RMSI payloads (e.g., 1002-1 . . . 1002-n) in memory. Theses stored RMSI payloads may be associated with version IDs V₀={v_{0,1}, v_{0,2}, . . . , v_{0,n}}.

At a later time, UE decodes the non-scheduling PDCCH 1004 and obtains version ID v associated with RMSI in the indicated time window. As indicated, the UE may attempt to decode the RMSI PDSCH 1008 only if v does not match any of the version IDs {v_{0,1}, v_{0,2}, . . . , v_{0,n}}. Otherwise, if there is a match, the UE may assume the RMSI PDSCH 1008 has the same payload as the stored RMSI corresponding to one of the matching version IDs (and can skip decoding the RMSI PDSCH 1008).

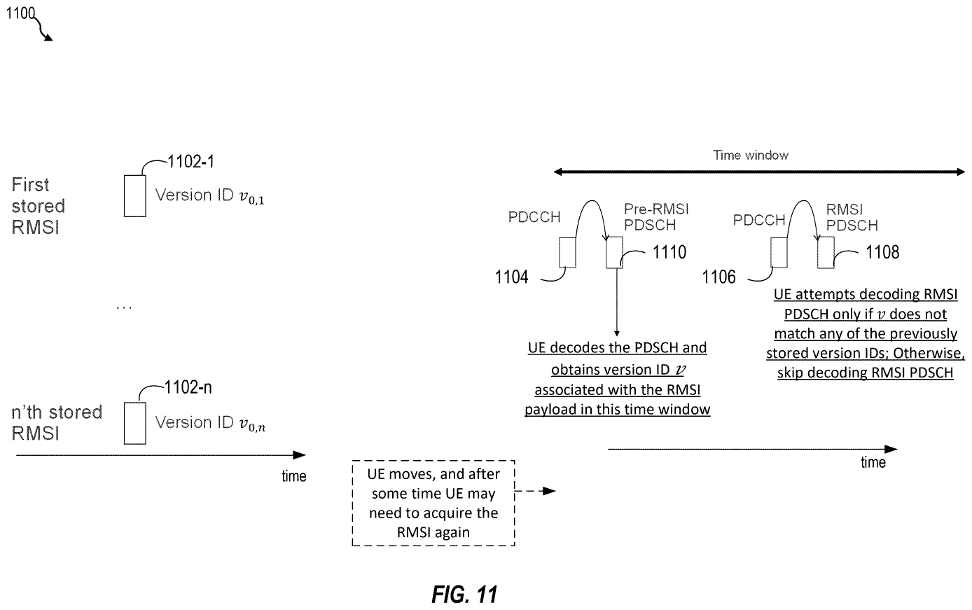

As illustrated in diagram 1100 of FIG. 11, a pre-RMSI PDSCH 1110 (e.g., a PDSCH that occurs prior to the RMSI PDSCH 1108) may include a version ID (v) associated with a subsequent RMSI payload (e.g., conveyed in an RMSI PDSCH 1108) received in a time window. The pre-RMSI PDSCH 1110 may be scheduled via a PDCCH 1104.

According to certain aspects, the time window may be fixed. For example, the time window may be based on the RMSI period (e.g., 160 ms in NR) or multiple RMSI periods that includes the pre-RMSI PDSCH 1110. In some cases, the time window may be indicated by the pre-RMSI PDSCH 1110.

According to certain aspects, the scheduling DCI (e.g., DCI format 1_0 in CSS) conveyed in PDCCH 1004 indicates whether the scheduled PDSCH is a pre-RMSI PDSCH or is the RMSI PDSCH. This indication may be conveyed via an explicit field or may be based on the RNTI (e.g., CRC mask of the DCI).

In the example illustrated in FIG. 11, it may be assumed that the UE has already stored one or more RMSI payloads (e.g., 1102-1 . . . 1102-n) in memory and that these stored RMSI payloads are associated with version IDs V₀={v_{0,1}, v_{0,2}, . . . , v_{0,n}}. As illustrated, the UE may decodes the pre-RMSI PDSCH 1110 and obtain version ID v associated with the RMSI payload (in RMSI PDSCH 1108) in this time window.

The UE may attempt decoding the scheduled RMSI PDSCH 1108 only if v does not match any of the version IDs {v_{0,1}, v_{0,2}, . . . , v_{0,n}}. Otherwise, UE may assume that the scheduled RMSI PDSCH 1108 has the same payload as the stored RMSI with matching version ID (and can skip decoding the scheduled RMSI PDSCH 1108).

According to certain aspects, a pre-RMSI PDSCH (as well as the RMSI PDSCH) may be PDCCH-less (e.g., not scheduled by DCI). In such cases, the resources of the pre-RMSI PDSCH and/or RMSI PDSCH may be fixed or may be indicated via MIB. In such cases, a pre-RMSI PDSCH may indicate transmission parameters, such as transport block size (TBS) and/or code rate, of the RMSI PDSCH (in addition to the version ID).

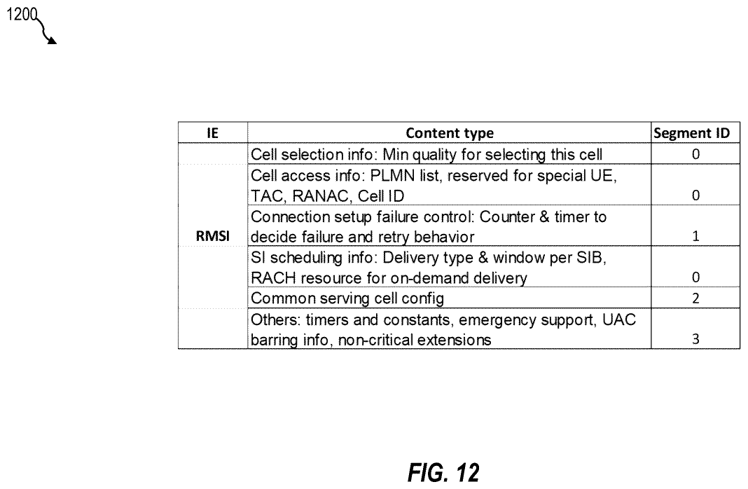

As illustrated in table 1200 of FIG. 12, in some cases, RMSI may have different segments. Such segments may change at different rates, with some changing more often than others.

According to certain aspects, the RMSI sharing techniques proposed herein (e.g., through using a stored RMSI payload with matching version ID in use case 1) may be applicable only to some segments of RMSI payload. For other segments of RMSI payload, the corresponding PDSCH may be decoded by the UE regardless of the version ID (i.e., version ID may not be applicable to such segments). In other words, a UE may attempt to decode these segments whether or not they have knowledge of a corresponding version ID.

The motivation for applying version based decoding to some segments, but not others, is that some parts of the RMSI information (in current NR) may be relatively constant/fixed across time/cells, while other parts of the RMSI information may be change more dynamically or may be cell-dependent.

Assuming the RMSI payload is divided into multiple segments, as shown in table 1200 of FIG. 12, each may be scheduled by a corresponding PDCCH and included in the corresponding scheduled PDSCH. Segmentation of RMSI may help reduce the payload size of each PDSCH (given that in multiplexing patterns 2/3, only 2 symbols RMSI PDSCH can be transmitted). The techniques proposed herein may be applied to any RMSI segment.

### Example Operations

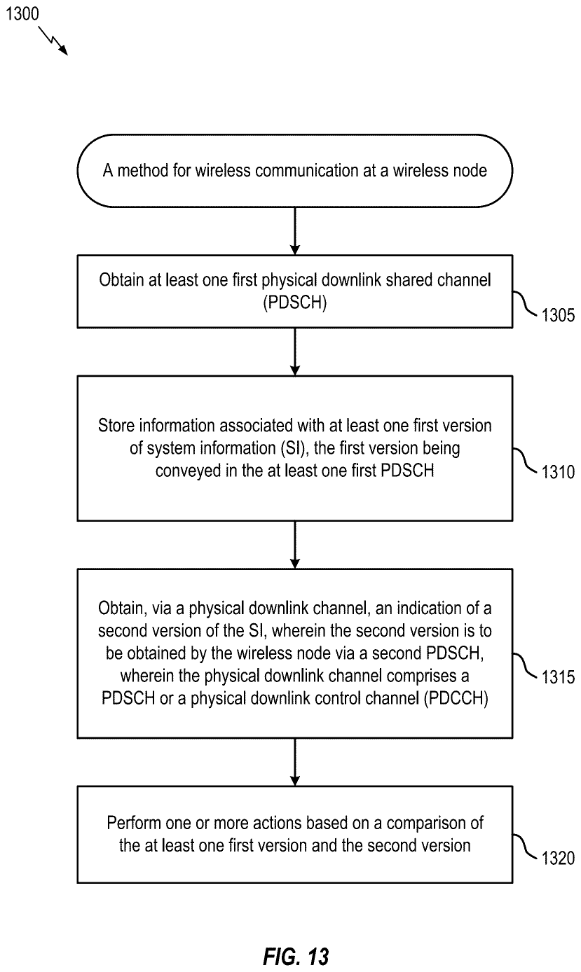

FIG. 13 shows an example of a method 1300 of wireless communication at a wireless node. In some examples, the wireless node is a user equipment, such as a UE 104 of FIGS. 1 and 3. In some examples, the wireless node is a network entity, such as a BS 102 of FIGS. 1 and 3, or a disaggregated base station as discussed with respect to FIG. 2.

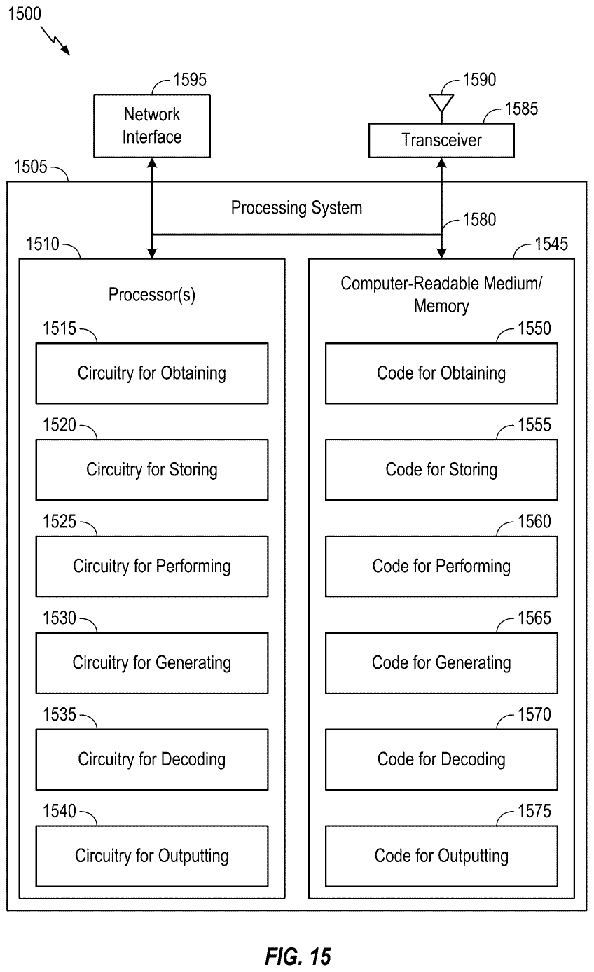

Method 1300 begins at step 1305 with obtaining at least one first physical downlink shared channel (PDSCH). In some cases, the operations of this step refer to, or may be performed by, circuitry for obtaining and/or code for obtaining as described with reference to FIG. 15.

Method 1300 then proceeds to step 1310 with storing information associated with at least one first version of system information (SI), the first version being conveyed in the at least one first PDSCH. In some cases, the operations of this step refer to, or may be performed by, circuitry for storing and/or code for storing as described with reference to FIG. 15.

Method 1300 then proceeds to step 1315 with obtaining, via a physical downlink channel, an indication of a second version of the SI, wherein the second version is to be obtained by the wireless node via a second PDSCH, wherein the physical downlink channel comprises a PDSCH or a physical downlink control channel (PDCCH). In some cases, the operations of this step refer to, or may be performed by, circuitry for obtaining and/or code for obtaining as described with reference to FIG. 15.

Method 1300 then proceeds to step 1320 with performing one or more actions based on a comparison of the at least one first version and the second version. In some cases, the operations of this step refer to, or may be performed by, circuitry for performing and/or code for performing as described with reference to FIG. 15.

In some aspects, at least one of: the physical downlink channel comprises a PDCCH; or the SI comprises remaining minimum system information (RMSI).

In some aspects, the method 1300 further includes obtaining, from the PDCCH, scheduling information associated with the second PDSCH. In some cases, the operations of this step refer to, or may be performed by, circuitry for obtaining and/or code for obtaining as described with reference to FIG. 15.

In some aspects, the stored information comprises a payload of the RMSI.

In some aspects, the method 1300 further includes generating soft bits as part of an unsuccessful attempt to decode the first version of RMSI, wherein the information comprises the soft bits. In some cases, the operations of this step refer to, or may be performed by, circuitry for generating and/or code for generating as described with reference to FIG. 15.

In some aspects, the one or more actions comprise: decoding the second PDSCH using the soft bits, if the second version matches the at least one first version.

In some aspects, the one or more actions comprise: skipping decoding the second PDSCH, if the second version matches the at least one first version and the information comprises a payload of the RMSI; or decoding the second PDSCH using soft combining, if the second version matches the at least one first version and the information comprises soft bits generated based on an unsuccessful attempt to decode the first version of RMSI.

In some aspects, the one or more actions comprise: skipping decoding the second PDSCH, if the second version matches the at least one first version; or decoding the second PDSCH, if the second version does not match the at least one first version.

In some aspects, the second version is associated with a time window in which the second PDSCH is scheduled.

In some aspects, the one or more actions comprise: skipping decoding the second PDSCH, if the second version matches the at least one first version and the wireless node obtains the second PDSCH in the time window; or decoding the second PDSCH, if the second version does not match the at least one first version and the second PDSCH is obtained in the time window.

In some aspects, the physical downlink channel comprises a third PDSCH; and the method further comprises obtaining a PDCCH that: schedules the third PDSCH; and indicates that the third PDSCH includes the indication of the second version.

In some aspects, the second PDSCH conveys a first segment of the second version of the SI; and the information comprises a first segment of the first version of SI.

In some aspects, the one or more actions comprise: skipping decoding the second PDSCH, if the second version matches the at least one first version; or decoding the second PDSCH to obtain the first segment of the second version of the SI, if the second version does not match the at least one first version.

In some aspects, the method 1300 further includes decoding a third PDSCH that conveys a second segment of the SI, the third PDSCH being decoded independent of whether the wireless node knows a corresponding version of the SI. In some cases, the operations of this step refer to, or may be performed by, circuitry for decoding and/or code for decoding as described with reference to FIG. 15.

In one aspect, method 1300, or any aspect related to it, may be performed by an apparatus, such as communications device 1500 of FIG. 15, which includes various components operable, configured, or adapted to perform the method 1300. Communications device 1500 is described below in further detail.

Note that FIG. 13 is just one example of a method, and other methods including fewer, additional, or alternative steps are possible consistent with this disclosure.

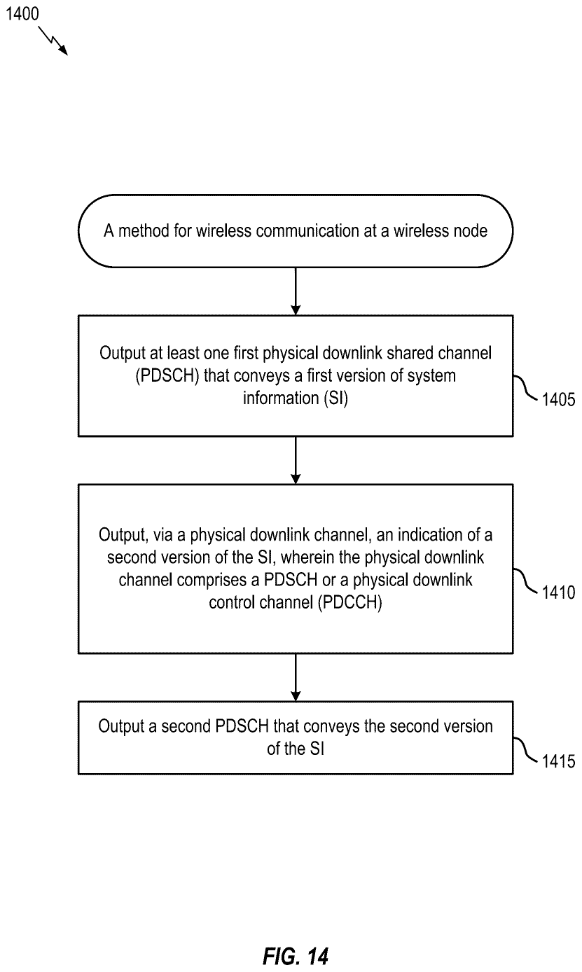

FIG. 14 shows an example of a method 1400 of wireless communication at a wireless node. In some examples, the wireless node is a user equipment, such as a UE 104 of FIGS. 1 and 3. In some examples, the wireless node is a network entity, such as a BS 102 of FIGS. 1 and 3, or a disaggregated base station as discussed with respect to FIG. 2.

Method 1400 begins at step 1405 with outputting at least one first physical downlink shared channel (PDSCH) that conveys a first version of system information (SI). In some cases, the operations of this step refer to, or may be performed by, circuitry for outputting and/or code for outputting as described with reference to FIG. 15.

Method 1400 then proceeds to step 1410 with outputting, via a physical downlink channel, an indication of a second version of the SI, wherein the physical downlink channel comprises a PDSCH or a physical downlink control channel (PDCCH). In some cases, the operations of this step refer to, or may be performed by, circuitry for outputting and/or code for outputting as described with reference to FIG. 15.

Method 1400 then proceeds to step 1415 with outputting a second PDSCH that conveys the second version of the SI. In some cases, the operations of this step refer to, or may be performed by, circuitry for outputting and/or code for outputting as described with reference to FIG. 15.

In some aspects, the SI comprises remaining minimum system information (RMSI).

In some aspects, the physical downlink channel comprises a physical downlink control channel (PDCCH).

In some aspects, the PDCCH includes scheduling information associated with the second PDSCH.

In some aspects, the second version is associated with a time window in which the second PDSCH is scheduled.

In some aspects, the physical downlink channel comprises a third PDSCH; and the method further comprises outputting a PDCCH that: schedules the third PDSCH; and indicates that the third PDSCH includes the indication of the second version.

In one aspect, method 1400, or any aspect related to it, may be performed by an apparatus, such as communications device 1500 of FIG. 15, which includes various components operable, configured, or adapted to perform the method 1400. Communications device 1500 is described below in further detail.

Note that FIG. 14 is just one example of a method, and other methods including fewer, additional, or alternative steps are possible consistent with this disclosure.

### Example Communications Device(s)

FIG. 15 depicts aspects of an example communications device 1500. In some aspects, communications device 1500 is a user equipment, such as UE 104 described above with respect to FIGS. 1 and 3. In some aspects, communications device 1500 is a network entity, such as BS 102 of FIGS. 1 and 3, or a disaggregated base station as discussed with respect to FIG. 2.

The communications device 1500 includes a processing system 1505 coupled to the transceiver 1585 (e.g., a transmitter and/or a receiver). In some aspects (e.g., when communications device 1500 is a network entity), processing system 1505 may be coupled to a network interface 1595 that is configured to obtain and send signals for the communications device 1500 via communication link(s), such as a backhaul link, midhaul link, and/or fronthaul link as described herein, such as with respect to FIG. 2. The transceiver 1585 is configured to transmit and receive signals for the communications device 1500 via the antenna 1590, such as the various signals as described herein. The processing system 1505 may be configured to perform processing functions for the communications device 1500, including processing signals received and/or to be transmitted by the communications device 1500.

The processing system 1505 includes one or more processors 1510. In various aspects, the one or more processors 1510 may be representative of one or more of receive processor 358, transmit processor 364, TX MIMO processor 366, and/or controller/processor 380, as described with respect to FIG. 3. In various aspects, one or more processors 1510 may be representative of one or more of receive processor 338, transmit processor 320, TX MIMO processor 330, and/or controller/processor 340, as described with respect to FIG. 3. The one or more processors 1510 are coupled to a computer-readable medium/memory 1545 via a bus 1580. In certain aspects, the computer-readable medium/memory 1545 is configured to store instructions (e.g., computer-executable code) that when executed by the one or more processors 1510, cause the one or more processors 1510 to perform the method 1300 described with respect to FIG. 13, or any aspect related to it; and the method 1400 described with respect to FIG. 14, or any aspect related to it. Note that reference to a processor performing a function of communications device 1500 may include one or more processors 1510 performing that function of communications device 1500.

In the depicted example, computer-readable medium/memory 1545 stores code (e.g., executable instructions), such as code for obtaining 1550, code for storing 1555, code for performing 1560, code for generating 1565, code for decoding 1570, and code for outputting 1575. Processing of the code for obtaining 1550, code for storing 1555, code for performing 1560, code for generating 1565, code for decoding 1570, and code for outputting 1575 may cause the communications device 1500 to perform the method 1300 described with respect to FIG. 13, or any aspect related to it; and the method 1400 described with respect to FIG. 14, or any aspect related to it.

The one or more processors 1510 include circuitry configured to implement (e.g., execute) the code stored in the computer-readable medium/memory 1545, including circuitry for obtaining 1515, circuitry for storing 1520, circuitry for performing 1525, circuitry for generating 1530, circuitry for decoding 1535, and circuitry for outputting 1540. Processing with circuitry for obtaining 1515, circuitry for storing 1520, circuitry for performing 1525, circuitry for generating 1530, circuitry for decoding 1535, and circuitry for outputting 1540 may cause the communications device 1500 to perform the method 1300 described with respect to FIG. 13, or any aspect related to it; and the method 1400 described with respect to FIG. 14, or any aspect related to it.

Various components of the communications device 1500 may provide means for performing the method 1300 described with respect to FIG. 13, or any aspect related to it; and the method 1400 described with respect to FIG. 14, or any aspect related to it. For example, means for transmitting, sending or outputting for transmission may include transceivers 354 and/or antenna(s) 352 of the UE 104 illustrated in FIG. 3, transceivers 332 and/or antenna(s) 334 of the BS 102 illustrated in FIG. 3, and/or the transceiver 1585 and the antenna 1590 of the communications device 1500 in FIG. 15. Means for receiving or obtaining may include transceivers 354 and/or antenna(s) 352 of the UE 104 illustrated in FIG. 3, transceivers 332 and/or antenna(s) 334 of the BS 102 illustrated in FIG. 3, and/or the transceiver 1585 and the antenna 1590 of the communications device 1500 in FIG. 15.

### Example Clauses

Implementation examples are described in the following numbered clauses:

Clause 1: A method for wireless communication at a wireless node, comprising: obtaining at least one first physical downlink shared channel (PDSCH); storing information associated with at least one first version of system information (SI), the first version being conveyed in the at least one first PDSCH; obtaining, via a physical downlink channel, an indication of a second version of the SI, wherein the second version is to be obtained by the wireless node via a second PDSCH, wherein the physical downlink channel comprises a PDSCH or a physical downlink control channel (PDCCH); and performing one or more actions based on a comparison of the at least one first version and the second version.

Clause 2: The method of Clause 1, wherein at least one of: the physical downlink channel comprises a PDCCH; or the SI comprises remaining minimum system information (RMSI).

Clause 3: The method of Clause 2, further comprising obtaining, from the PDCCH, scheduling information associated with the second PDSCH.

Clause 4: The method of Clause 2, wherein the stored information comprises a payload of the RMSI.

Clause 5: The method of any one of Clauses 1-4, wherein the one or more actions comprise: skipping decoding the second PDSCH, if the second version matches the at least one first version; or decoding the second PDSCH, if the second version does not match the at least one first version.

Clause 6: The method of Clause 2, further comprising: generating soft bits as part of an unsuccessful attempt to decode the first version of RMSI, wherein the information comprises the soft bits.

Clause 7: The method of Clause 6, wherein the one or more actions comprise: decoding the second PDSCH using the soft bits, if the second version matches the at least one first version.

Clause 8: The method of Clause 2, wherein the one or more actions comprise: skipping decoding the second PDSCH, if the second version matches the at least one first version and the information comprises a payload of the RMSI; or decoding the second PDSCH using soft combining, if the second version matches the at least one first version and the information comprises soft bits generated based on an unsuccessful attempt to decode the first version of RMSI.

Clause 9: The method of any one of Clauses 1-8, wherein: the second version is associated with a time window in which the second PDSCH is scheduled.

Clause 10: The method of Clause 9, wherein the one or more actions comprise: skipping decoding the second PDSCH, if the second version matches the at least one first version and the wireless node obtains the second PDSCH in the time window; or decoding the second PDSCH, if the second version does not match the at least one first version and the second PDSCH is obtained in the time window.

Clause 11: The method of Clause 9, wherein: the physical downlink channel comprises a third PDSCH; and the method further comprises obtaining a PDCCH that: schedules the third PDSCH; and indicates that the third PDSCH includes the indication of the second version.

Clause 12: The method of any one of Clauses 1-11, wherein: the second PDSCH conveys a first segment of the second version of the SI; and the information comprises a first segment of the first version of SI.

Clause 13: The method of Clause 12, wherein the one or more actions comprise: skipping decoding the second PDSCH, if the second version matches the at least one first version; or decoding the second PDSCH to obtain the first segment of the second version of the SI, if the second version does not match the at least one first version.

Clause 14: The method of Clause 12, further comprising decoding a third PDSCH that conveys a second segment of the SI, the third PDSCH being decoded independent of whether the wireless node knows a corresponding version of the SI.

Clause 15: A method for wireless communication at a wireless node, comprising: outputting at least one first physical downlink shared channel (PDSCH) that conveys a first version of system information (SI); outputting, via a physical downlink channel, an indication of a second version of the SI, wherein the physical downlink channel comprises a PDSCH or a physical downlink control channel (PDCCH); and outputting a second PDSCH that conveys the second version of the SI.

Clause 16: The method of Clause 15, wherein the SI comprises remaining minimum system information (RMSI).

Clause 17: The method of Clause 16, wherein the physical downlink channel comprises a physical downlink control channel (PDCCH).

Clause 18: The method of Clause 17, wherein the PDCCH includes scheduling information associated with the second PDSCH.

Clause 19: The method of any one of Clauses 15-18, wherein: the second version is associated with a time window in which the second PDSCH is scheduled.

Clause 20: The method of Clause 19, wherein: the physical downlink channel comprises a third PDSCH; and the method further comprises outputting a PDCCH that: schedules the third PDSCH; and indicates that the third PDSCH includes the indication of the second version.

Clause 21: An apparatus, comprising: at least one memory comprising executable instructions; and at least one processor configured to execute the executable instructions and cause the apparatus to perform a method in accordance with any combination of Clauses 1-20.

Clause 22: An apparatus, comprising means for performing a method in accordance with any combination of Clauses 1-20.

Clause 23: A non-transitory computer-readable medium comprising executable instructions that, when executed by at least one processor of an apparatus, cause the apparatus to perform a method in accordance with any combination of Clauses 1-20.

Clause 24: A computer program product embodied on a computer-readable storage medium comprising code for performing a method in accordance with any combination of Clauses 1-20.

Clause 25: A wireless node (e.g., a user equipment (UE)), including: at least one transceiver; at least one memory including executable instructions; and at least one processor configured to execute the executable instructions and cause the wireless node to perform a method in accordance with any combination of Clauses 1-14, wherein the at least one transceiver is configured to receive the at least one first PDSCH.

Clause 26: A wireless node (e.g., a network entity), including: at least one transceiver; at least one memory including executable instructions; and at least one processor configured to execute the executable instructions and cause the wireless node to perform a method in accordance with any combination of Clauses 15-20, wherein the at least one transceiver is configured to transmit the at least one first PDSCH.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The various illustrative logical blocks, modules and circuits described in connection with the present disclosure may be implemented or performed with a general purpose processor, a graphics processing unit (GPU), a neural processing unit (NPU), a digital signal processor (DSP), an ASIC, a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, a system on a chip (SoC), or any other such configuration.

As used herein, “a processor,” “at least one processor” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

In some cases, rather than actually transmitting a signal, an apparatus (e.g., a wireless node or device) may have an interface to output the signal for transmission. For example, a processor may output a signal, via a bus interface, to a radio frequency (RF) front end for transmission. Accordingly, a means for outputting may include such an interface as an alternative (or in addition) to a transmitter or transceiver. Similarly, rather than actually receiving a signal, an apparatus (e.g., a wireless node or device) may have an interface to obtain a signal from another device. For example, a processor may obtain (or receive) a signal, via a bus interface, from an RF front end for reception. Accordingly, a means for obtaining may include such an interface as an alternative (or in addition) to a receiver or transceiver.

While the present disclosure may describe certain operations as being performed by one type of wireless node, the same or similar operations may also be performed by another type of wireless node. For example, operations performed by a user equipment (UE) may also (or instead) be performed by a network entity (e.g., a base station or unit of a disaggregated base station). Similarly, operations performed by a network entity may also (or instead) be performed by a UE.

Further, while the present disclosure may describe certain types of communications between different types of wireless nodes (e.g., between a network entity and a UE), the same or similar types of communications may occur between same types of wireless nodes (e.g., between network entities or between UEs, in a peer-to-peer scenario). Further, communications may occur in reverse order than described.

Means for obtaining, means for storing, means for performing, means for generating, means for decoding, means for skipping, means for using, and means for outputting may comprise one or more processors, such as one or more of the processors described above with reference to FIG. 15.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

The methods disclosed herein comprise one or more actions for achieving the methods. The method actions may be interchanged with one another without departing from the scope of the claims. In other words, unless a specific order of actions is specified, the order and/or use of specific actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Software shall be construed broadly to mean instructions, instruction sets, code, code segments, program code, programs, subprograms, software modules, applications, software applications, software packages, routines, subroutines, objects, executables, threads of execution, procedures, or functions, whether referred to as software, firmware, middleware, microcode, hardware description language, or otherwise.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for”. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. An apparatus for wireless communication, comprising:
at least one memory comprising computer-executable instructions; and
one or more processors configured to execute the computer-executable instructions and cause the apparatus to:
obtain at least one first physical downlink shared channel (PDSCH);
store information associated with at least one first version of system information (SI), the first version being conveyed in the at least one first PDSCH;
obtain, via a physical downlink channel, an indication of a second version of the SI, wherein the second version is to be obtained by the apparatus via a second PDSCH, wherein the physical downlink channel comprises a PDSCH or a physical downlink control channel (PDCCH); and
perform one or more actions based on a comparison of the at least one first version and the second version.

2. The apparatus of claim 1, wherein at least one of:
the physical downlink channel comprises a PDCCH; or
the SI comprises remaining minimum system information (RMSI).

3. The apparatus of claim 2, wherein the one or more processors are further configured to cause the apparatus to obtain, from the PDCCH, scheduling information associated with the second PDSCH.

4. The apparatus of claim 2, wherein the stored information comprises a payload of the RMSI.

5. The apparatus of claim 1, wherein the one or more actions comprise:
skipping decoding the second PDSCH, if the second version matches the at least one first version; or
decoding the second PDSCH, if the second version does not match the at least one first version.

6. The apparatus of claim 2, wherein the one or more processors are further configured to cause the apparatus to:
generate soft bits as part of an unsuccessful attempt to decode the first version of RMSI, wherein the information comprises the soft bits.

7. The apparatus of claim 6, wherein the one or more actions comprise:
decoding the second PDSCH using the soft bits, if the second version matches the at least one first version.

8. The apparatus of claim 2, wherein the one or more actions comprise:
skipping decoding the second PDSCH, if the second version matches the at least one first version and the information comprises a payload of the RMSI; or
decoding the second PDSCH using soft combining, if the second version matches the at least one first version and the information comprises soft bits generated based on an unsuccessful attempt to decode the first version of RMSI.

9. The apparatus of claim 1, wherein:
the second version is associated with a time window in which the second PDSCH is scheduled.

10. The apparatus of claim 9, wherein the one or more actions comprise:
skipping decoding the second PDSCH, if the second version matches the at least one first version and the apparatus obtains the second PDSCH in the time window; or
decoding the second PDSCH, if the second version does not match the at least one first version and the second PDSCH is obtained in the time window.

11. The apparatus of claim 9, wherein:
the physical downlink channel comprises a third PDSCH; and
the one or more processors are further configured to cause the apparatus to obtain a PDCCH that:
schedules the third PDSCH; and
indicates that the third PDSCH includes the indication of the second version.

12. The apparatus of claim 1, wherein:
the second PDSCH conveys a first segment of the second version of the SI; and
the information comprises a first segment of the first version of SI.

13. The apparatus of claim 12, wherein the one or more actions comprise:
skipping decoding the second PDSCH, if the second version matches the at least one first version; or
decoding the second PDSCH to obtain the first segment of the second version of the SI, if the second version does not match the at least one first version.

14. The apparatus of claim 12, wherein the one or more processors are further configured to cause the apparatus to decode a third PDSCH that conveys a second segment of the SI, the third PDSCH being decoded independent of whether the apparatus knows a corresponding version of the SI.

15. The apparatus of claim 1, further comprising at least one transceiver configured to receive the at least one first PDSCH, wherein the apparatus is configured as a user equipment (UE).

16. An apparatus for wireless communication, comprising:
at least one memory comprising computer-executable instructions; and
one or more processors configured to execute the computer-executable instructions and cause the apparatus to:
output at least one first physical downlink shared channel (PDSCH) that conveys a first version of system information (SI);
output, via a physical downlink channel, an indication of a second version of the SI, wherein the physical downlink channel comprises a PDSCH or a physical downlink control channel (PDCCH); and
output a second PDSCH that conveys the second version of the SI.

17. The apparatus of claim 16, wherein the SI comprises remaining minimum system information (RMSI).

18. The apparatus of claim 17, wherein the physical downlink channel comprises a physical downlink control channel (PDCCH).

19. The apparatus of claim 18, wherein the PDCCH includes scheduling information associated with the second PDSCH.

20. The apparatus of claim 16, wherein:
the second version is associated with a time window in which the second PDSCH is scheduled.

21. The apparatus of claim 20, wherein:
the physical downlink channel comprises a third PDSCH; and
the one or more processors are further configured to cause the apparatus to output a PDCCH that:
schedules the third PDSCH; and
indicates that the third PDSCH includes the indication of the second version.

22. The apparatus of claim 16, further comprising at least one transceiver configured to transmit the at least one first PDSCH, wherein the apparatus is configured as a network entity.

23. A method for wireless communication at a wireless node, comprising:
obtaining at least one first physical downlink shared channel (PDSCH);
storing information associated with at least one first version of system information (SI), the first version being conveyed in the at least one first PDSCH;
obtaining, via a physical downlink channel, an indication of a second version of the SI, wherein the second version is to be obtained by the wireless node via a second PDSCH, wherein the physical downlink channel comprises a PDSCH or a physical downlink control channel (PDCCH); and
performing one or more actions based on a comparison of the at least one first version and the second version.
